(19) United States
(12) Patent Application Publication
(10) Pub. No.: US 2019/0138669 A1
(43) Pub. Date: May 9, 2019

(54) METHOD FOR DETERMINING POLLUTANT EMISSIONS FROM A VEHICLE USING MACROSCOPIC PARAMETERS

(71) Applicant: IFP Energies nouvelles, Rueil-Malmaison (FR)

(72) Inventors: Laurent THIBAULT, LYON (FR); Philippe DEGEILH, PARIS (FR); Gilles CORDE, IGNY (FR)

(21) Appl. No.: 16/090,942

(22) PCT Filed: Feb. 14, 2017
(86) PCT No.: PCT/EP2017/053307

§ 371 Date: Oct. 3, 2018

(30) Foreign Application Priority Data
Apr. 4, 2016 (FR) 1652924

(51) Int. Cl. G06F 17/50

(52) U.S. Cl. CPC G06F 17/5009; F01N 9/005; F01N 2900/12

(57) ABSTRACT

The invention relates to a method for determining pollutant emissions from a vehicle (PSEE, pollutant emissions from the post-treatment system), said method being based on the use of measurements of the position (pos_{GPS}) and/or the altitude (alt_{GPS}) and/or the speed of the vehicle (v_{GPS}), using models of the vehicle (MOD VEH), the engine (MOD MOT) and the post-treatment system (MOD POT) produced with macroscopic parameters (PAR).

The present invention relates to the field of modeling pollutant emissions from a vehicle, in particular from a motor vehicle.

The estimation of the pollutant emissions from vehicles in actual use is a major issue in order to face up to the public and environmental health challenges encountered in large cities. To achieve this, the approach mainly used at present consists in instrumenting a vehicle with the aid of a portable emissions measurement system (PEMS). However, the cost of these systems remains prohibitive and does not enable the large-scale distribution thereof. Consequently, they do not make it possible to measure the pollutant emissions in actual use on a large scale.

In order to overcome this problem linked to this instrumentation, there are various modelling approaches. The prior art of pollutant models consists of two main families, macroscopic models and microscopic models. The field of the invention is here on the vehicle scale, i.e. the macroscopic scale. High-frequency (microscopic scale) models that model the physical phenomena involved in the combustion in an extremely detailed manner, as for example described in patent application FR2984557 (US 2013/0158967), are not suitable for estimating the pollutant emissions in actual use and on a large scale due to the prohibitive calculation time thereof, and also the large number of parameters required.

With macroscopic approaches, the most common model uses emissions factors, i.e. average coefficients of emissions per kilometer travelled. These coefficients depend on the pollutant considered, on the average speed over the journey, on the type of motorization (gasoline/diesel) and on the Euro standard of the vehicle. Mention may in particular be made of patent application CN102054222A which couples GPS acquisitions with emissions factors. However, these approaches only consider an average behavior of the vehicle and of the driver, and do not therefore make it possible to model their actual usage. In particular, the impact of the driving style on the emissions is neglected therein. They make it possible to estimate the total average emissions over a total run of a sufficiently long duration.

Moreover, many studies are based on emission factors for estimating the pollutant emissions. Mention may particular be made of the document by Liu, H., Chen, X., Wang, Y., & Han, S. (2013). Vehicle Emission and Near-Road Air Quality Modeling for Shanghai, China: Based on Global Positioning System Data from Taxis and Revised MOVES Emission Inventory. Transportation Research Record: Journal of the Transportation Research Board, (2340), 38-48, in which GPS data connected to taxis are used as input data for emissions factors, and the document by Sentoff, K. M., Aultman-Hall, L., & Holmen, B. A. (2015). Implications of driving style and road grade for accurate vehicle activity data and emissions estimates. Transportation Research Part D: Transport and Environment, 35, 175-188, which studies the accuracy of the estimation by emission factor. The conclusion of the latter study shows that the main source of error originates from not taking into account the impact of the driving style and of the grade. Yet, in order to capture these phenomena, it is necessary to use a finer model level, referred to as a microscopic pollutant model, the input data of which is a vehicle speed signal of 1 Hertz.

Furthermore, numerous microscopic models already exist, designed to be used within the context of an engineering study, which are unsuitable for onboard implementation, for example on a smartphone or on a server. The best-known microscopic models are the comprehensive modal emissions model (CMEM) and the Passenger Car and Heavy Duty Emission Model (PHEM) which take, as input data, instantaneous speed profiles. The CMEM model, developed in the 1990s by the University of California (Riverside), represented a significant contribution when it came out, but today has two major drawbacks: inaccurate results due to excessive simplifications, and a poor consideration of diesel motorizations.

As regards the PHEM model, it has the limitation of only proposing one model type for numerous relatively different vehicles. Several documents have already studied the coupling of these microscopic models with GPS data, provided by connected boxes installed in the vehicle. Mention may particular be made of the document by Pluvinet, P., Gonzalez-Feliu, J., & Ambrosini, C. (2012). GPS data analysis for understanding urban goods movement. Procedia-Social and Behavioral Sciences, 39, 450-462 which gives details of a study where actual GPS (global positioning system) data were used to supply a microscopic emission model. However, this study has a major limitation since the type of vehicle and the type of engine are not taken into account. Taking into account the type of vehicle and motorization is a major problem for modelling pollutant emissions in actual use on a large scale. Specifically, although it is possible to recover the GPS measurements, it is much more complicated to know the technical specifications of its engine and to consequently configure the model. However, these specifications are essential for configuring the abovementioned microscopic models. This is a major limitation of existing microscopic models that cannot be used for large-scale deployment since they require tedious manual configuration work for each vehicle considered.

In order to overcome these drawbacks, the present invention relates to a process for determining pollutant emissions from a vehicle, the process is based on the use of measurements of the position and/or altitude and/or speed of the vehicle, by means of models of the vehicle, of the engine and of the aftertreatment system constructed with macroscopic parameters. Thus, it is possible to determine the pollutant emissions from the vehicle without specific instrumentation, for actual use (owing to the measurements), with a limited calculation time (owing to the models), and accurately (owing to the models constructed with the aid of macroscopic parameters).

### The Process According to the Invention

The present invention relates to a process for determining pollutant emissions from a vehicle, said vehicle having an internal combustion engine and a system for aftertreatment of the exhaust gases of said engine, wherein at least one macroscopic parameter relating to the design of said vehicle is acquired, and wherein the following are constructed for said vehicle:
i) a model of said vehicle which connects said position and/or the altitude and/or the speed of said vehicle to the torque and to the rating of said engine by means of at least one macroscopic parameter;
ii) a model of said engine which connects said torque and said rating of said engine to the pollutant emissions leaving said engine by means of at least one macroscopic parameter; and
iii) a model of said aftertreatment system which connects said pollutant emissions leaving said engine to the pollutant emissions leaving said aftertreatment system by means of at least one macroscopic parameter.

For this process, the following steps are carried out:
a) the position, and/or the altitude and/or the speed of said vehicle are measured;
b) said torque and said rating of said engine are determined by means of said vehicle model and said measurements;
c) the pollutant emissions leaving said engine are determined by means of said engine model and said torque and said rating of said engine; and
d) the pollutant emissions from the vehicle are determined by means of said aftertreatment system model and said pollutant emissions leaving said engine.

According to an embodiment, a preprocessing of said measurements is carried out before the step of determining said torque and said rating of the engine.

Advantageously, said preprocessing is carried out by means of an oversampling and a filtering.

Preferably, at least one macroscopic parameter is acquired which is chosen from: the type of motorization, the certification standard, the engine swept volume, the maximum torque and the rating of the associated engine, the maximum power and the rating of the associated engine, the weight of the vehicle, the type of transmission of the vehicle, the type of aftertreatment system, the type of injection system, the architecture of the air loop.

In accordance with one embodiment, said macroscopic parameters are acquired from a database and/or by means of an interface with a user.

According to one feature, said vehicle model is constructed by means of a model of the dynamics of the vehicle connecting said position and/or the altitude and/or said speed of the vehicle to the estimated power of said engine by means of at least one macroscopic parameter, and by means of a model of the transmission connecting said engine power to the rating and to the torque of the engine by means of at least one macroscopic parameter.

According to one variant, said engine model is constructed by means of an energetic model connecting said rating and said torque of the engine to temperatures and flow rates of fluids used by the combustion within said engine by means of at least one macroscopic parameter, and by means of a model of pollutants leaving said engine connecting said temperatures and said flow rates of fluids to the pollutant emissions leaving said engine by means of at least one macroscopic parameter.

In accordance with one embodiment option, said model of pollutants leaving said engine is constructed by means of a quasi-static model and of a transient model, these two models connecting said temperatures and said flow rates of fluids to said pollutant emissions leaving said engine by means of at least one macroscopic parameter.

Advantageously, said transient model corresponds to a corrective coefficient of said quasi-static model.

In accordance with one embodiment, said aftertreatment model is constructed by discretization of said aftertreatment system into several slices and by means of the efficiency of each discretized slice.

According to one implementation, said vehicle emissions determined are stored in a database.

Advantageously, said pollutants are chosen from nitrogen oxides, particulates, carbon monoxides and/or unburnt hydrocarbons.

In accordance with one feature, the position and/or the altitude and/or the speed of the vehicle are measured by means of a geolocation system or a cell phone.

Preferably, the pollutant emissions determined are displayed on a screen of a geolocation system, of a cell phone, of a dashboard of the vehicle or on an Internet site.

Furthermore, the invention relates to a computer program product downloadable from a communication network and/or saved on a medium that can be read by a computer and/or that can be executed by a processor or a server, comprising program code instructions for the implementation of the process according to one of the preceding features, when said program is executed on a computer or on a cell phone.

Moreover, the invention relates the use of the process according to one of the preceding features, for estimating the ecological efficiency of a road infrastructure or a road traffic regulation.

### BRIEF DESCRIPTION OF THE FIGURES

Other features and advantages of the process according to the invention will become apparent on reading the description below of nonlimiting examples of embodiments, with reference to the appended figures described below.

FIG. 1 illustrates the steps of the process according to one embodiment of the invention.

FIG. 2 is a histogram comparing NOx emissions for several journeys for a reference and the process according to the invention.

### DETAILED DESCRIPTION OF THE INVENTION

The present invention relates to the determining of emissions of pollutants from a vehicle. The term “pollutants” denotes nitrogen oxides (NOx), particulates, carbon monoxides (CO), and unburnt hydrocarbons (HC). The process according to the invention makes it possible to determine the emissions of at least one, advantageously several, and preferably all, of these pollutants.

The vehicle has an internal combustion engine (denoted hereinafter by the term “engine”) and a system for aftertreatment of the exhaust gases of the engine. The internal combustion engine may be a gasoline engine or a diesel engine. The engine may move the vehicle by itself, or may be part of a hybrid propulsion system. The aftertreatment system makes it possible to treat the pollutant emissions leaving the engine, thus reducing the pollutant emissions of the vehicle. The aftertreatment system may comprise an oxidation catalyst for treating the unburnt hydrocarbons and the carbon monoxide, and/or DeNOx catalysts for reducing the nitrogen oxides in the presence of oxygen, and/or various filters for eliminating the solid particulates.

For the process according to the invention, at least one macroscopic parameter relating to the design of the vehicle is acquired. A macroscopic parameter refers to a general feature relating to the vehicle, its engine or its aftertreatment system. It is a constant parameter for a vehicle, corresponding to vehicle manufacturer data. The parameter is referred to as macroscopic because it is determined on the scale of the vehicle, and it is not a microscopic parameter which can be determined, like for example in patent application FR2984557 (US 2013/0158967), on the scale of a grid cell representing a small portion of the combustion chamber. Macroscopic parameters enable the construction of macroscopic models that are representative of the vehicle.

The macroscopic parameters may be of three types:
parameters linked to the general construction of the vehicle (for example: weight of the vehicle, transmission, etc.),
parameters linked to the motorization (for example: the type of injection, the swept volume, the type of motorization, etc.), and
parameters linked to the aftertreatment system (for example: type of aftertreatment).

According to one embodiment of the invention, it is possible to acquire at least one macroscopic parameter chosen from:
the type of motorization (gasoline, diesel, etc.),
the certification standard level (Euro 1, Euro 2, etc.),
the engine swept volume,
the maximum torque and the rating of the associated engine,
the maximum power and the rating of the associated engine,
the weight of the vehicle,
the type of transmission of the vehicle (type and composition of gearbox, etc.),
the type of aftertreatment system,
the type of injection system,
the architecture of the air loop, (presence/absence of a recirculation of the burnt gases, denoted by EGR, use of a turbocompressor, of supercharging, etc.),
the dimensions of the wheels, etc.

According to one embodiment variant, the macroscopic parameters may be obtained from a database, which lists the various vehicles in circulation. For example, the macroscopic parameters may be obtained by indicating the license number of the vehicle, the database matching the plate number to its design (make, model, motorization, etc.), and comprising the macroscopic parameters of the vehicle.

Alternatively, the macroscopic parameters may be manufacturer data supplied by the user, in particular by means of an interface (for example a smart phone or a geolocation system).

### Notations

In the remainder of the description, the following notations are used:
pos_{GPS} Coordinates measured by geolocation in the Lambert system [m]
alt_{GPS} Altitude measured by geolocation [m]
v_{GPS} Vehicle speed measured by geolocation [m/s]
v Vehicle speed [m/s]
Ne Estimated engine rating [rev/min]
Cme Estimated engine torque [Nm]
m Weight of the vehicle [kg]
F_{T} Tractive force of the vehicle at the wheel [N]
Fᵣₑₛ Resultant of the friction forces experienced by the vehicle [N]
Fₛₗₒₚₑ Normal force experienced by the vehicle (gravity) [N]
F_{brk} Mechanical braking force [N]
α Angle of inclination of the road [rad]
a, b, c Vehicle parameters [-]
Pe Estimated engine power [kW]
ηₜᵣₐₙₛ Transmission efficiency [-]
R_{MTH-v} Reduction ratio between the speed of rotation of the engine and the speed of the vehicle [rpm/km/h]
PSME Pollutant emissions leaving the engine [g/s]
PSMEᵢ Emissions of pollutant i leaving the engine [g/s]
PSMEi_{-QS} Emissions of pollutant i leaving the engine for a quasi-static regime [g/h]
NOx_{QS} Weight of Nox per unit weight of fuel [g/kg de carburant]
COC Crankshaft angle at the centre of combustion (50% energy conversion) [° CA]
m_{cyl} Weight of air enclosed in the cylinder per cycle [g/10³ cm³]
m_{O2} Weight of oxygen enclosed in the cylinder per cycle [g/10³ cm³]
a₀, a₁, a₂, a₃ Coefficients [-]
Soot_{QS} Emissions of particulates leaving the engine in quasi-static regime [g/s]
BGR Fraction of burnt gases in the cylinder [%]
BGR_{dyn} Dynamic fraction of burnt gases in the cylinder [%]
AFᵣₐₜᵢₒ Richness of the mix in the cylinder [-]
AF_{ratio-dyn} Dynamic richness of the mixed in the cylinder [-]
Cor_{i-QS2TR} Correction coefficient for the impact of transient phenomena for polluant i [-]
PSEE Pollutant emissions leaving the aftertreatment system [g/s]
PSEEᵢ Emissions of pollutant i leaving the aftertreatment system [g/s]
Conv_{i,j} Conversion efficiency of the slice j of the aftertreatment system for polluant i [-]
Texh Temperature of the exhaust gases [K]
Qexh Flow rate of the exhaust gases [g/s]

For these notations, the derivative with respect to time is denoted by

$$\frac{d}{dt} .$$

In the present application, the term f generally denotes a function, which may be of any type.

According to the invention, three macroscopic models are constructed in order to determine the pollutant emissions. These models are configured with the macroscopic parameters acquired, thus making it possible to render the process according to the invention representative of the vehicle. These are a vehicle model, an engine model and an aftertreatment model (i.e. a model of the aftertreatment system). These models do not require specific instrumentation or equipment on the vehicle.

Vehicle Model

The vehicle model connects the position and/or the altitude and/or the speed of the vehicle to the torque and to the rating of said engine, by means of at least one macroscopic parameter. According to one implementation of the invention, in order to construct the vehicle model, it is possible to use at least one of the following macroscopic parameters: weight of the vehicle, maximum power and rating of the associated engine, maximum speed, type of transmission, etc.

According to one embodiment of the invention, it is possible to construct the vehicle model by combination of a model of the dynamics of the vehicle and a model of the transmission of the vehicle. The model of the dynamics of the vehicle connects the position and/or the speed and/or the altitude of the vehicle to the estimated power of the vehicle by means of at least one macroscopic parameter, for example the weight of the vehicle, the type of transmission, the dimensions of the wheels. The model of the transmission of the vehicle connects the power of the vehicle to the rating and to the torque of the engine, by means of at least one macroscopic parameter, for example the type of transmission, the maximum power and the associated engine rating.

The model of the dynamics of the vehicle takes into account the dynamics of the vehicle. It may be constructed from the application of the fundamental principle of dynamics of the vehicle applied to its longitudinal axis, and can be written in the following form:

$$m \frac{dv}{dt} = {F}_{T} - {F}_{res} - {F}_{slope} - {F}_{brk}$$

with:

v is the speed of the vehicle, input data of the model of the vehicle dynamics.

Fᵣₑₛ can be expressed as a function of the speed in the form Fᵣₑₛ=a+bv+cv² with a, b, c being parameters of the vehicle to be identified as function of the general characteristics of the vehicle (macroscopic parameters of the vehicle).

Fₛₗₒₚₑ can be expressed as a function of the weight of the vehicle and of the inclination α of the road: Fₛₗₒₚₑ=mg sin(α). The angle of inclination α is input data of the model of the vehicle dynamics. Specifically, the inclination α can be calculated from the altitude and from the distance travelled, it therefore depends on the altitude and the position. According to one embodiment, the angle of inclination α can be determined by a formula of the type:

$$α = arctan ( \frac{Δ altitude}{Δ distance} )$$

These equations make it possible to write a formula which connects the estimated power of the engine to the speed of the vehicle and other macroscopic parameters that are known or can be determined. Specifically, it is possible to write the equation:

Pe=F_{T}*v/ηₜᵣₐₙₛ

Thus, by combining the various equations, it is possible to determine a formula which connects the power of the engine to the speed and altitude of the vehicle, by means of known and constant macroscopic parameters.

The model of the transmission estimates the reduction ratio between the speed of rotation of the combustion engine and the speed of the vehicle. It can be configured as a function of the general features (macroscopic parameters) of the vehicle, in particular the weight of the vehicle, the maximum power, the type of transmission, in particular the number of ratios. This model of the transmission uses only the speed of the vehicle as input data, for estimating the reduction ratio:

R_{MTH-v}=f(v)

The function f may be obtained in particular from nomograms provided by the manufacturer.

This reduction ratio may then be used to determine the rating of the engine. Specifically, it is possible to write the following relationships:

Ne=R_{MTH-v}*v

Next, the torque of the engine can be determined as a function of the power (estimated with the aid of the model of the dynamics of the vehicle) and of the rating of the engine:

Cme=f(Ne,Pe)

The function f may be obtained by mappings supplied by the manufacturer.

Engine Model

The engine model connects the rating and the torque of the engine to the pollutant emissions leaving the engine (i.e. before the aftertreatment system), by means of at least one macroscopic parameter. According to one implementation of the invention, in order to construct the engine model it is possible to use at least one of the following macroscopic parameters: the swept volume, the type of motorization, the torque and the power, the architecture of the air loop, the certification standard of the vehicle, etc.

According to one embodiment of the invention, it is possible to construct the engine model by combination of an energetic model and a model of pollutants leaving the engine. The energetic model connects the torque and the rating of the engine to flow rates and temperatures of fluids used in the combustion engine (fuels, intake gases, exhaust gases, optionally recirculation of the burnt gases) by means of at least one macroscopic parameter, for example the swept volume, the type of motorization, the maximum torque and the maximum power, the architecture of the air loop. The model of pollutants leaving the engine connects flow rates and temperatures of fluids used in the internal combustion engine to the pollutant emissions leaving the engine, by means of at least one macroscopic parameter, for example the certification standard of the vehicle, the type of motorization, the architecture of the air loop.

The energetic model makes it possible to estimate the physical quantities over the current operating point (rating, torque). It is configured as a function of macroscopic parameters. The physical quantities estimated are the flow rates and temperatures of the fluids used in the combustion engine (fuels, intake gases, exhaust gases, optionally recirculation of the burnt gases).

The model of pollutants leaving the engine makes it possible, from the information on the rating and on the torque of the engine, and the estimations derived from the energetic model, to estimate the pollutant emissions leaving the engine. It can be configured as a function of the general features of the vehicle and of the engine: the certification standard of the vehicle, the type of motorization, the architecture of the air loop, etc.

The estimation of the pollutants leaving the engine can be carried out in two steps:
estimation of the quasi-static emissions by means of a quasi-static model, and
estimation of the impact of transient phenomena by means of a transient model.

Alternatively, the estimation of the pollutants leaving the engine can be carried out solely in a single step by means of the quasi-static model.

Estimating the quasi-static emissions of an engine over an operating point at a given instant comes down to considering that this engine is in stabilized operation over this operating point.

The estimation of the impact of transient phenomena (non-stabilized operation) makes it possible to take into account the transient phenomena, which generally produce a surplus of pollutant emissions.

The quasi-static models of pollutants may be configured by means of macroscopic parameters of the vehicle and of the engine. They make it possible, at each instant, to estimate the quasi-static pollutant emissions leaving the engine, from estimations of the rating and torque of the combustion engine, and from outputs of the energetic model. The quasi-static models can be written in the form:

PSME_{i-QS}=f(Ne,Cme)

The function f may be of a different type, depending on the type of pollutant studied.

For example, the quasi-static model of NOx may be derived from the works by Gartner, (U. Gartner, G. Hohenberg, H. Daudel and H. Oelschlegel, Development and Application of a Semi-Empirical NOx Model to Various HD Diesel Engines), and can be written in the form:

log(NOx_{QS})=a₀+a₁*COC+a₂*m_{cyl}+a₃*m_{O2}

The coefficients a₀, a₁, a₂, a₃ are obtained from experimental data. One of the advantages of this model is that these coefficients vary little from one engine to another. This point is demonstrated in the aforementioned article by Gartner.

The particulates leaving the engine are a combination of two phenomena: the formation and the post-oxidation in the combustion chamber. These phenomena are, to the first order, influenced by the richness, the rating, the amount of fuel, and the proportion of burnt gases. Thus, the static model of particulates leaving the engine can be written as an equation of the form:

Soot_{QS}=f(AFᵣₐₜᵢₒ,Ne,Fuel,BGR)

The function f can be determined by correlation with experimental data.

Similar models can be constructed for the other pollutants.

For the embodiment for which the impact of the transient phenomena is determined, it is possible to additionally use the means described below. The air loop dynamics phenomena generate a difference in the BGR proportions (fraction of burnt gases, linked to the recirculation of the exhaust gases) and the richness relative to the stabilized operating point, which has a strong impact on the pollutants, in particular the hydrocarbons HC, the carbon monoxide CO and particulates. The models of the impact of the transient phenomenon are configured as a function of macroscopic parameters of the engine, in particular characteristics of the air loop recovered (atmospheric/supercharged, high-pressure burnt gas recirculation EGR_{HP}/low-pressure burnt gas recirculation EGR_{BP}).

These models make it possible to estimate the dynamic fractions of burnt gases and dynamic richnesses from quasi-static estimations and from the variation of the estimated torque:

BGR_{dyn}=f(BGR,Cme,dCme/dt)

AF_{ratio-dyn}=f(AFᵣₐₜᵢₒ,Cme,dCme/dt)

A correction coefficient for each pollutant can be calculated as a function of these dynamic quantities:

Cor_{i-QS2TR}=f(BGR_{dyn},BGR,AF_{ratio-dyn},AFᵣₐₜᵢₒ)

These correction coefficients make it possible to estimate the pollutant emissions leaving the engine by taking into account the transient phenomena. For this, the pollutant emissions leaving the engine can be written by a formula of the type:

PSMEᵢ=Cor_{i-QS2TR}*PSME_{i-QS}

Aftertreatment Model

The aftertreatment model connects the pollutant emissions leaving the engine (i.e. before the aftertreatment system) to the pollutant emissions leaving the aftertreatment system, by means of at least one macroscopic parameter. According to one implementation of the invention, in order to construct the aftertreatment model it is possible to use at least one of the following macroscopic parameters: the swept volume, the certification standard of the vehicle, etc.

The aftertreatment model may comprise sub-models for each pollution control technology, which are combined as a function of the architecture of the pollution control system of the vehicle. These sub-models may be configured as a function of macroscopic parameters of the vehicle such as the certification standard, the swept volume, etc. For example, the various pollution control technologies may be:
TWC, which stands for three-way catalytic converter,
GPF (for a gasoline engine), which stands for gasoline particulate filter,
DOC (for a diesel engine), which stands for diesel oxidation catalyst,
DPF (for a diesel engine), which stands for diesel particulate filter,
LNT (for a diesel engine), which stands for lean Nox trap,
SCR (for a diesel engine), which stands for selective catalytic reduction.

The aftertreatment model makes it possible to estimate the pollutant emissions leaving the aftertreatment system from estimations of temperature, flow rates and pollutant emissions leaving the engine. The aftertreatment model may be constructed by discretizing the aftertreatment system into several slices (or layers), and by combining the efficiency Conv_{i,j} of each discretized slice. According to an example, the aftertreatment model may be written:

$${PSSE}_{i} = {\prod }_{j = 1}^{No . of slices} {Conv}_{i , j} ( {T}_{exh} , {Q}_{exh} ) * {PSME}_{i}$$

The efficiency of the slices of the aftertreatment system can be determined from manufacturer mappings.

Steps of the Process for Determining Pollutant Emissions

Once the models are constructed for the vehicle in question, the process according to the invention comprises the following steps:

1) Geolocation measurement

2) (optional step) Preprocessing of the measurements

3) Determination of the torque and of the engine rating

4) Determination of the pollutant emissions leaving the engine

5) Determination of the pollutant emissions from the vehicle

6) (optional step) Storage of the data

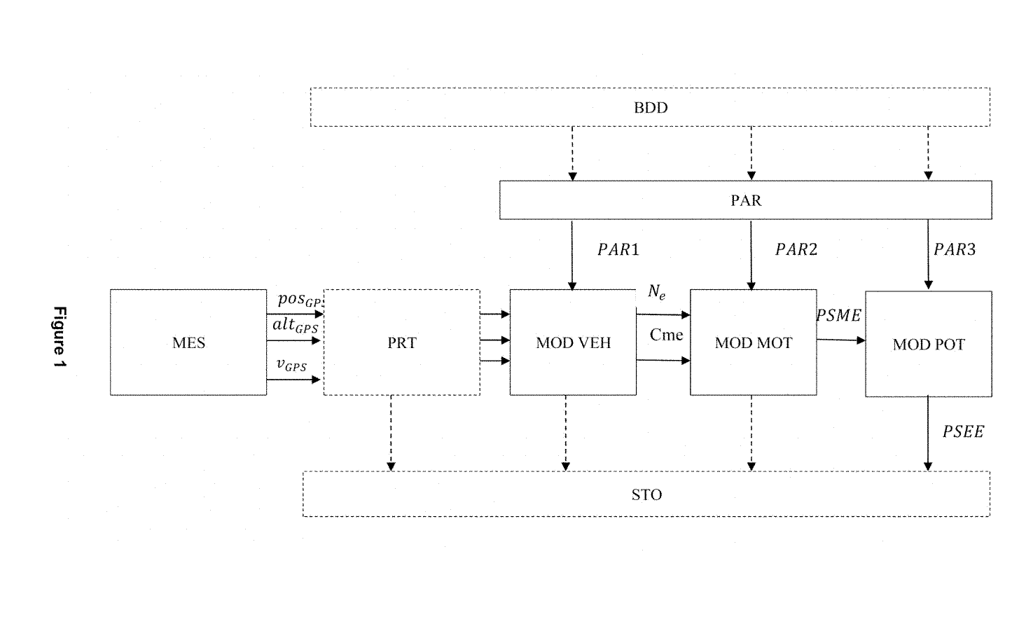

FIG. 1 illustrates, schematically end non-limitingly, the steps of the process according to one embodiment of the invention. In this figure, the dotted lines indicate optional elements of the process.

Prior to the steps of the process, the various models (vehicle model MOD VEH, engine model MOD MOT and aftertreatment model MOD POT) are constructed. These models are constructed from macroscopic parameters PAR. Optionally, the macroscopic parameters PAR may be obtained from a database BDD, which lists the various vehicles in circulation. For example, the macroscopic parameters PAR may be obtained by indicating the license number of the vehicle, the database BDD matching the plate number to the design of the vehicle (make, model, motorization, etc.), and comprising the macroscopic parameters of the vehicle.

A first series of macroscopic parameters PAR1 is used for the construction of the vehicle model MOD VEH. This first series of macroscopic parameters PAR1 may comprise the following parameters: weight of the vehicle, maximum power and rating of the associated engine, maximum speed, type of transmission, (nonlimiting list).

A second series of macroscopic parameters PAR2 is used for the construction of the engine model MOD MOT. This second series of macroscopic parameters PAR2 may comprise the following parameters: the swept volume, the type of motorization, the maximum torque and the maximum power, the architecture of the air loop, the certification standard of the vehicle, (nonlimiting list).

A third series of macroscopic parameters PAR3 is used for the construction of the aftertreatment model MOD POT. This third series of macroscopic parameters PAR3 may comprise the following parameters: the swept volume, the certification standard of the vehicle, (nonlimiting list).

These three models may be constructed according to one of the embodiment variants described above.

The first step consists of a step of geolocation measuring step MES. During this step, it is possible to measure the position pos_{GPS}, and/or the altitude alt_{GPS} and/or the speed v_{GPS} of the vehicle. Taking into account the altitude alt_{GPS} makes it possible in particular to take into account the road grade. Preferably, the three measurements are carried out so as to have as precise as possible information regarding the geolocation of the vehicle, since it is then possible to take into account the driving style, and the acceleration of the vehicle. This measurement may be carried out using a geolocation system, for example of GPS (global positioning system) type or of Galileo type, or by means of a smart phone, etc. In the case of a smart phone, the latter may be equipped with a geolocation system, alternatively the measurements may be carried out by other means, in particular by triangulation.

The second step, which is an optional step, is a preprocessing step PRT of the measurement signals. This step makes it possible to improve the quality of the signals measured before using them. This step may in particular be advantageous, if the measurements are carried out using a smart phone, since the measurements derived from such a device may be somewhat imprecise. This preprocessing may be variable since it is dependent on the quality of the input data. According to one embodiment of the invention, the preprocessing PRT may comprise an oversampling of the signals, then a filtering. After this step, signals relating to the position pos_{GPS}, and/or the altitude alt_{GPS} and/or the speed v_{GPS} of the vehicle are therefore recovered, the signals having been preprocessed.

The third step relates to the determination of the torque and of the engine rating. This step is carried out by means of the vehicle model MOD VEH, which determines the torque Cme and the rating Ne of the engine, as a function of the geolocation data: the position pos_{GPS}, and/or the altitude alt_{GPS} and/or the speed v_{GPS} of the vehicle.

The fourth step relates to the determination of the pollutant emissions leaving the engine, this step is carried out by means of the engine model MOD MOT, which determines the pollutant emissions leaving the engine PSME, as a function of the torque Cme and the rating Ne of the engine.

The fifth step relates to the determination of the pollutant emissions from the vehicle, i.e. leaving the aftertreatment system. The determination of the pollutant emissions may be carried out at each instant, for example at a frequency of 1 Hz. Furthermore, it is also possible to determine the total pollutant emissions over a journey undertaken. This step is implemented by means of the aftertreatment model MOD POT, which determines the pollutant emissions leaving the aftertreatment system PSEE, as a function of the pollutant emissions leaving the engine PSME.

The optional sixth step relates to the storage of data. Once the pollutant emissions from the vehicle PSEE are determined, these may be stored STO (saved), in particular in a database (different from the database which contains the macroscopic parameters). This storage STO may relate solely to the pollutant emissions from the vehicle PSEE, but may also relate to the data determined after each step of the process: the preprocessed measurements and/or the torque Cme and the rating Ne of the engine and/or the emissions of pollutants leaving the engine PSME. These pieces of information enable a monitoring of the actual usages and of the associated emissions with good spatial and temporal resolution. These pieces of information may for example make it possible to evaluate the environmental relevance of road infrastructures on the scale of a street, to identify localized emission peaks, to identify the impact of the driving style on the emissions, etc.

This database may combine the instantaneous emissions with mapping data in order to form a map of actual pollutant emissions. It is therefore possible to draw conclusions on the scale of a portion of road, a complete journey or even a geographical zone according to the requirements. During this step, it is also possible to display the pollutant emissions leaving the vehicle PSEE, for example on a screen of a geolocation system (GPS, Galileo), of a smart phone, on the dashboard of the vehicle, on an Internet site, etc. Thus, it is possible to inform the user or any other person (for example a manager of a fleet of vehicles, a person responsible for road infrastructure, etc.) of the pollution emitted over a journey or over a road.

The process according to the invention may be used for motor vehicles. However, it may be used in the field of road transport, the field of two-wheeled vehicles, the railroad field, the maritime field, the aeronautical field, the field of hovercraft, and field of amphibious vehicles, etc.

The invention furthermore relates to a computer program product downloadable from a communication network and/or saved on a medium that can be read by a computer and/or that can be executed by a processor or a server. This program comprises program code instructions for the implementation of the process as described above, when the program is executed on a computer or on a cell phone.

The process according to the invention therefore has the following advantages:
the process according to the invention enables the grade, the acceleration and the driving style to be taken into account, for precisely determining the pollutant emissions,
the modelling of the pollutants according to the invention is carried out by a physical approach that only requires knowledge of macroscopic parameters, which are readily available, for example using the license plate of a vehicle,
the process according to the invention is designed for the actual parameters of each of the vehicles,
the process according to the invention does not require data measured in the engine bank, which would be specific to a vehicle,
the process according to the invention makes it possible to model a class of vehicle,
the process according to the invention does not require specific instrumentation or equipment, indeed the pollutant emissions may be determined by means of a geolocation device or a smart phone,
the process according to the invention makes it possible to place the pollutant emissions over the roads travelled,
the invention makes it possible to estimate the ecological efficiency of an existing road infrastructure, without requiring the expensive installation of specific pollutant sensors,
it also makes it possible to observe the impact of a regulation relating to traffic or to vehicles on the pollutant emissions in actual use.

### EXAMPLE

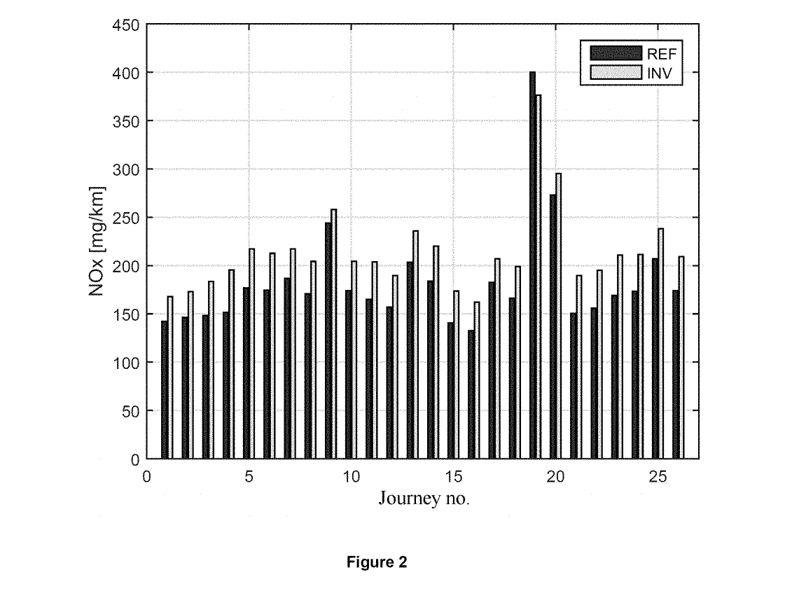

In order to show the advantage of the process according to the invention, an example is carried out in order to compare the NOx emissions measured and the emissions estimated by means of the models used in the process according to the invention. FIG. 2 illustrates a comparison of the results obtained, in terms of NOx emissions, for 26 different journeys, indicated by their number (Journey no.). In this histogram, the reference REF is from a series of tests, and the estimated values are obtained by the process according to the invention INV (using the embodiment variants of the models described in detail above). A good consistency of the results is observed.

1.-16. (canceled)

17. A process for determining pollution emissions from a vehicle, the vehicle having an internal combustion engine and a system for aftertreatment of the exhaust gases from the engine, wherein at least one macroscopic parameter relating to design of the vehicle is acquired, and wherein the following models are constructed for the vehicle comprising:
i) a model of the vehicle which connects at least one of the position, altitude and speed of the vehicle to torque and to rating of the engine by use of at least one macroscopic parameter;
ii) a model of the engine which connects the torque and the rating of the engine to emissions of pollutants leaving the engine by use of at least one macroscopic parameter; and
iii) a model of the aftertreatment system which connects the emission of pollutants from engine to the emissions of pollutants from the aftertreatment system by use of at least one macroscopic parameter; comprising steps of:
a. measuring at least one of the position, the altitude and the speed of the vehicle;
b. determining the torque and the rating of the engine by use of the vehicle model and the measurements;
c. determining the emissions of pollutants leaving the engine by use of the engine model and the torque and the rating of the engine; and
d. determining the emissions of pollutants from the vehicle by use of use aftertreatment system model and the emission pollutants from the engine.

18. The process as claimed in claim 17, comprising performing a preprocessing of the measurements is before the determining of the torque and the rating of the engine.

19. The process as claimed in claim 18, wherein the performing of the preprocessing is carried out by oversampling and filtering of the measurements.

20. The process as claimed in claim 17, comprising acquiring at least one macroscopic parameter is chosen from a type of motorization, a certification standard, engine displacement volume, maximum torque and rating of the internal combustion engine, maximum internal combustion energy power and rating of internal combustion engine, weight of the vehicle, type of transmission of the vehicle, type of aftertreatment system, type of injection system, an architecture of an air loop of the internal combustion engine.

21. The process as claimed in claim 17, wherein the macroscopic parameters are acquired from at least one of a database and from an interface with a user.

22. The process as claimed in claim 17, wherein the vehicle model is constructed by use of a model of dynamics of the vehicle connecting at least one of position, altitude and the speed of the vehicle to estimated power of the engine by use of at least one macroscopic parameter, and by means of a model of the transmission connecting the engine power to a rating and to torque of the engine by use of at least one macroscopic parameter.

23. The process as claimed in claim 17, comprising constructing the engine model by use of a model connecting the rating and the torque of the engine to temperatures and flow rates of fluids used by the internal combustion engine within the engine by use of at least one macroscopic parameter, and by use of a model of pollutants leaving the engine which connects the temperatures and the flow rates of fluids to emissions of pollutants from the engine by use of at least one macroscopic parameter.

24. The process as claimed in claim 23, wherein the model of pollutants from engine is constructed by use of a quasi-static model and of a transient model, which models connect the temperatures and the flow rates of fluids to emissions of pollutants leaving the engine by use of at least one macroscopic parameter.

25. The process as claimed in claim 24, wherein the transit model corresponds to a corrective coefficient of the quasi-static model.

26. The process as claimed in claim 17, comprising constructing the aftertreatment model by discretization of the aftertreatment system into slices and by use of efficiency of each slice.

27. The process as claimed in claim 17, wherein the determined emissions from the vehicle are stored in a database.

28. The process as claimed in claim 17, comprising choosing pollutants from at least one of nitrogen oxides, particulates, carbon monoxides and unburnt hydrocarbons.

29. The process as claimed in claim 17, wherein the at least one of position, altitude and speed of the vehicle are measured by use of a geolocation system or a cell phone.

30. The process as claimed in claim 17, wherein the emissions of pollutants which are determined are displayed on one of a screen of a geolocation system, a cell phone, a dashboard of the vehicle or an Internet site.

31. A computer program product downloadable from a communication network saved on a non transient tangible medium which is readable by a computer or can be executed by a processor or a server, comprising program code instructions for the implementation of the process as claimed in claim 17, when the program is executed on one of a computer or on a cell phone.

32. The use of the process as claimed in claim 17 comprising estimating one of ecological efficiency of a road infrastructure or a road traffic regulation.
